(19) United States
(12) Patent Application Publication
(10) Pub. No.: US 2026/0190689 A1
(43) Pub. Date: Jul. 2, 2026

(54) DISPLAY DEVICE

(71) Applicant: AUO Corporation, Hsinchu City (TW)

(72) Inventors: Yi-Ting Yeh, Hsinchu City (TW); Kent-Yi Lee, Hsinchu City (TW); Yu-Sheng Huang, Hsinchu City (TW); Wan-Tsang Wang, Hsinchu City (TW)

(73) Assignee: AUO Corporation, Hsinchu City (TW)

(21) Appl. No.: 19/224,915

(22) Filed: Jun. 2, 2025

(30) Foreign Application Priority Data
Dec. 31, 2024 (TW) 113151723

(51) Int. Cl. H10K 59/131; H10H 29/49

(52) U.S. Cl. CPC H10K 59/131; H10H 29/49

(57) ABSTRACT

A display device includes a substrate, a pixel structure, a signal line, and a first inorganic insulating pattern. The substrate has an island region, a bridge region, and a connection region. The connection region is adjacent to the island region and is connected to the bridge region. The pixel structure is disposed in the island region and includes a light emitting element. The signal line is located in the bridge region, extends to the connection region, and is electrically connected to the pixel structure. The first inorganic insulating pattern is located in the connection region and has a notch. An orthographic projection of the signal line on the substrate overlaps with an orthographic projection of the notch on the substrate.

### CROSS-REFERENCE TO RELATED APPLICATION

This application claims the priority benefit of Taiwan application serial no. 113151723, filed on Dec. 31, 2024. The entirety of the above-mentioned patent application is hereby incorporated by reference herein and made a part of this specification.

### BACKGROUND

### Technical Field

The disclosure relates to a photoelectric device, and more particularly to a display device.

### Description of Related Art

As display devices continue to innovate, stretchable, flexible, and unrestricted appearance features are gradually gaining attention to meet requirements of arbitrarily stretching or bending the display devices of users. In order to improve the stretchability and the flexibility of the display device as much as possible, a current approach is to make pixel units into an island-shaped form, and adopt a circuit structure in a bridge-shaped form to connect the pixel units in pairs.

However, the current stretchable display devices often have metal residues between adjacent signal lines at junctions of the pixel units and the circuit structure, causing signal line short circuits and signal abnormalities, resulting in reduced product yield.

### SUMMARY

The disclosure provides a display device with improved product yield.

The disclosure provides a method for manufacturing a display device, which can improve the product yield of the display device.

An embodiment of the disclosure provides a display device, which includes a substrate, a pixel structure, a signal line, and a first inorganic insulating pattern. The substrate has an island region, a bridge region, and a connection region. The connection region is adjacent to the island region and is connected to the bridge region. The pixel structure is disposed in the island region and includes a light emitting element. The signal line is located in the bridge region, extends to the connection region, and is electrically connected to the pixel structure. The first inorganic insulating pattern is located in the connection region and has a notch. An orthographic projection of the signal line on the substrate overlaps with an orthographic projection of the notch on the substrate.

In an embodiment of the disclosure, the notch has an arc-shaped outline.

In an embodiment of the disclosure, a part of the first inorganic insulating pattern overlapping with the signal line has a first maximum size, a part of the first inorganic insulating pattern not overlapping with the signal line has a second maximum size, and the first maximum size is smaller than the second maximum size.

In an embodiment of the disclosure, the first inorganic insulating pattern is located between the substrate and the signal line.

In an embodiment of the disclosure, the display device further includes an additional signal line. The additional signal line is located between the substrate and the first inorganic insulating pattern.

In an embodiment of the disclosure, the first inorganic insulating pattern has an opening The opening divides the first inorganic insulating pattern.

In an embodiment of the disclosure, the opening is communicated with the notch.

In an embodiment of the disclosure, the signal line overlaps with the opening.

In an embodiment of the disclosure, the signal line includes a first signal line and a second signal line, and the first inorganic insulating pattern has multiple notches. The first signal line and the second signal line respectively overlap with the notches.

In an embodiment of the disclosure, the first signal line and the second signal line are respectively connected to a first signal source and a second signal source.

In an embodiment of the disclosure, the display device further includes multiple second inorganic insulating patterns. The second inorganic insulating patterns are located in the bridge region and are physically separated from each other.

In an embodiment of the disclosure, a part of the second inorganic insulating patterns overlaps with the signal line, and another part of the second inorganic insulating patterns does not overlap with the signal line.

In an embodiment of the disclosure, the display device further includes an organic insulating layer. The organic insulating layer surrounds the signal line, the first inorganic insulating pattern, and the second inorganic insulating patterns.

In an embodiment of the disclosure, the light emitting element includes a micro light emitting diode or an organic light emitting diode.

In an embodiment of the disclosure, the island region has a rectangular outline, and the bridge region has a U-shaped, V-shaped, or S-shaped outline.

An embodiment of the disclosure provides a method for manufacturing a display device, which includes the following steps. A first inorganic insulating pattern is formed in a connection region of a substrate. The first inorganic insulating pattern has a notch, and the first inorganic insulating pattern has an acute angle at the notch. A conductive layer is formed on the substrate and the first inorganic insulating pattern. The conductive layer is etched to form a signal line. An orthographic projection of the signal line on the substrate overlaps with an orthographic projection of the notch of the first inorganic insulating pattern on the substrate.

In an embodiment of the disclosure, in a direction of the orthographic projection, the first inorganic insulating pattern is located between the signal line and the substrate.

In an embodiment of the disclosure, the acute angle of the first inorganic insulating pattern is removed while etching the conductive layer.

In an embodiment of the disclosure, multiple second inorganic insulating patterns are formed in a bridge region of the substrate while forming the first inorganic insulating pattern. The connection region connects the bridge region, and the second inorganic insulating patterns are physically separated from each other.

In an embodiment of the disclosure, the method further includes forming a light emitting element in an island region of the substrate. The connection region is located between the island region and the bridge region, and the light emitting element is electrically connected to the signal line.

In order for the features and advantages of the disclosure to be more comprehensible, the following specific embodiments are described in detail in conjunction with the drawings.

### BRIEF DESCRIPTION OF THE DRAWINGS

FIG. 1A is a partial top schematic view of a display device according to an embodiment of the disclosure.

FIG. 1B is a circuit schematic view of an embodiment of a pixel structure of the display device of FIG. 1A.

FIG. 1C is an enlarged schematic view of a connection region of the display device of FIG. 1A.

FIG. 1D is a cross-sectional schematic view taken along a section line A-A′ of FIG. 1C.

FIG. 1E is a cross-sectional schematic view taken along a section line B-B′ of FIG. 1A.

FIG. 1F is a cross-sectional schematic view taken along a section line C-C′ of FIG. 1A.

FIG. 1G is a partial top schematic view of an inorganic insulating pattern of the display device of FIG. 1A.

FIG. 2A to FIG. 4A are partial cross-sectional schematic views of steps of a method for manufacturing the display device of FIG. 1A.

FIG. 2B to FIG. 4B are respectively partial schematic top schematic views of FIG. 2A to FIG. 4A.

FIG. 5 is a top schematic view of a connection region of a display device according to an embodiment of the disclosure.

FIG. 6 is a top schematic view of a connection region of a display device according to an embodiment of the disclosure.

FIG. 7 is a top schematic view of a connection region of a display device according to an embodiment of the disclosure.

FIG. 8 is a partial top schematic view of a display device according to an embodiment of the disclosure.

FIG. 9 is a partial top schematic view of a display device according to an embodiment of the disclosure.

### DESCRIPTION OF THE EMBODIMENTS

Taking into account the measurements in question and the particular amount of measurement-related error associated (i.e., limitations of the measurement system), “about”, “approximately”, or “substantially” as used herein includes the stated value and an average value that is within an acceptable deviation range of a particular value as determined by one of ordinary skill in the art. For example, “about” may represent within one or more standard deviations or within ±30%, ±20%, ±10%, or ±5% of the stated value. Furthermore, an acceptable deviation range or standard deviation may be selected for “about”, “approximately”, or “substantially” used herein according to optical properties, etching properties, or other properties, and one standard deviation may not apply to all properties.

Furthermore, relative terms such as “lower” or “bottom” and “upper” or “top” may be used herein to describe the relationship between an element and another element, as shown in the figures. It will be understood that the relative terms are intended to include different orientations of a device in addition to the orientation depicted in the figures. For example, if the device in one of the figures is flipped, elements described as being on the “lower” side of other elements will then be oriented as being on the “upper” side of the other elements. Thus, the exemplary term “lower” may include the orientations of “lower” and “upper”, depending on the particular orientation of the figure. Similarly, if the device in one of the figures is flipped, elements described as “under” or “below” other elements will then be oriented “above” the other elements. Thus, the exemplary terms “under” or “below” may include both the orientations of above and below.

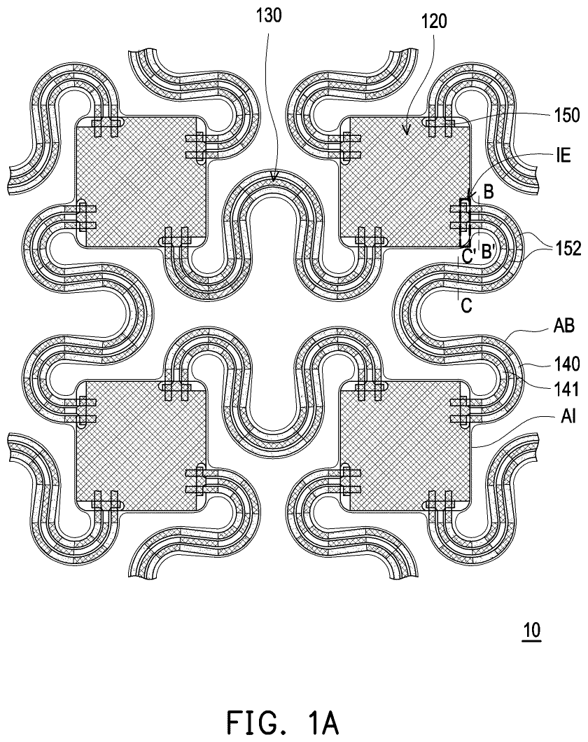

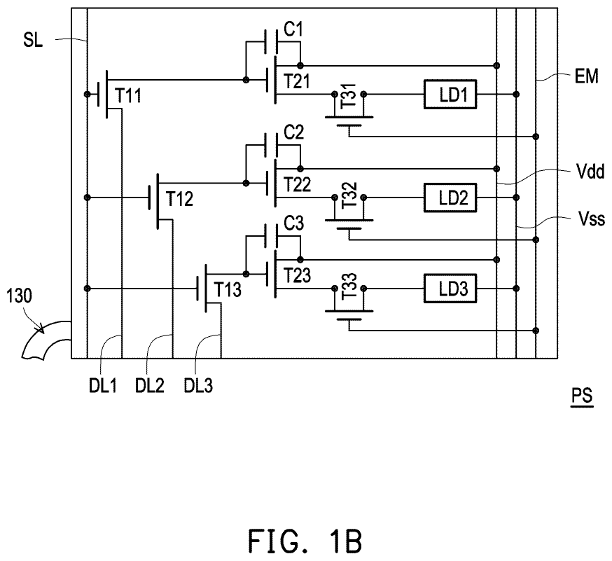

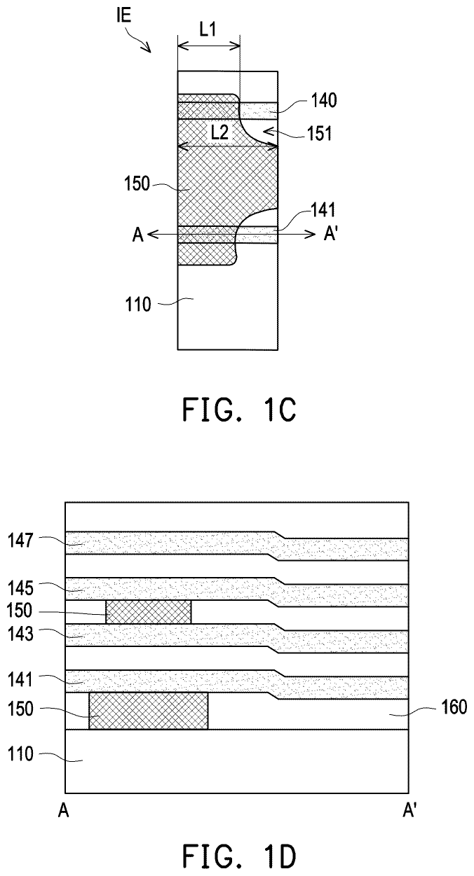

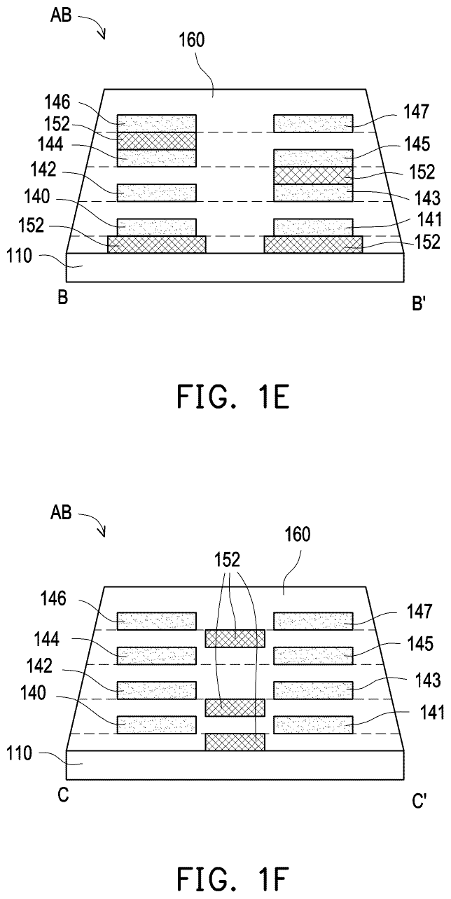

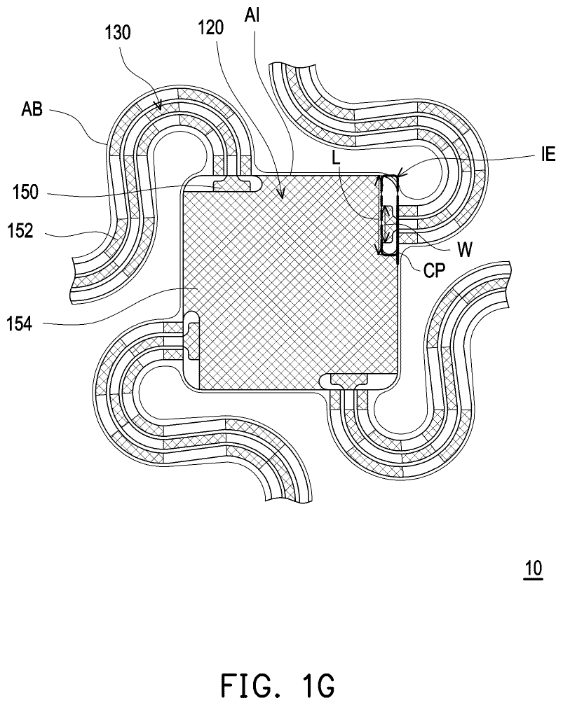

FIG. 1A is a partial top schematic view of a display device 10 according to an embodiment of the disclosure. FIG. 1B is a circuit schematic view of an embodiment of a pixel structure PS of the display device 10 of FIG. 1A. FIG. 1C is an enlarged schematic view of a connection region IE of the display device 10 of FIG. 1A. FIG. 1D is a cross-sectional schematic view taken along a section line A-A′ of FIG. 1C. FIG. 1E is a cross-sectional schematic view taken along a section line B-B′ of FIG. 1A. FIG. 1F is a cross-sectional schematic view taken along a section line C-C′ of FIG. 1A. FIG. 1G is a partial top schematic view of an inorganic insulating pattern 150 of the display device 10 of FIG. 1A. Hereinafter, the implementation of each element and film layer of the display device 10 will be further described with reference to FIG. 1A to FIG. 1G, but the disclosure is not limited thereto.

First, please refer to FIG. 1A. The display device 10 includes a substrate 110. The substrate 110 may have an island region AI, a bridge region AB, and the connection region IE, wherein the connection region IE may be adjacent to the island region AI, and the connection region IE may be connected to the bridge region AB. In some embodiments, the island region AI and the connection region IE jointly form a rectangular outline, but not limited thereto. In other embodiments, the island region AI and the connection region IE may have various geometrical outlines as required, such as a circle, a polygon, or an irregular shape. In some embodiments, the bridge region AB has a U-shaped outline, but not limited thereto.

The substrate 110 of the display device 10 may be a flexible substrate. The material of the substrate 110 may be, for example, polyimide (PI), polycarbonate (PC), polyester (PET), cyclic olefin copolymer (COC), metallocene-based cyclic olefin copolymer (mCOC), or other appropriate materials, but not limited thereto.

The display device 10 may further include an island portion 120 and a bridge portion 130, wherein the island portion 120 may be disposed in the island region AI, and the bridge portion 130 may be disposed in the bridge region AB. In some embodiments, the island region AI may refer to a region where the island portion 120 is located, and the bridge region AB may refer to a region where the bridge portion 130 is located. The substrate 110 of the display device 10 may be configured to support the island portion 120 and the bridge portion 130. The bridge portion 130 may be electrically connected to the island portion 120.

In some embodiments, the substrate 110 has multiple island regions AI, multiple bridge regions AB, and multiple connection regions IE. The bridge regions AB may be respectively located between two island regions AI. The connection regions IE may be respectively adjacent to the island region AI and may connect the corresponding bridge region AB and island region AI. In some embodiments, one island region AI may be respectively connected to multiple bridge regions AB through multiple connection regions IE. In some embodiments, the display device 10 includes multiple island portions 120 and multiple bridge portions 130. The island portions 120 are respectively disposed in the island regions AI, and the bridge portions 130 are respectively disposed in the bridge regions AB and are each electrically connected to two island portions 120.

In some embodiments, the island regions AI of the substrate 110 are arranged in an array, and the island portions 120 of the display device 10 are respectively disposed in the island regions AI and are correspondingly arranged in an array. For example, the island portions 120 may be arranged side by side.

Please refer to FIG. 1B. Each island portion 120 may, for example, form a pixel or a sub-pixel of the display device 10. The island portion 120 may include a pixel structure PS. In some embodiments, the pixel structure PS includes a light emitting element LD. The light emitting element LD may be, for example, a micro light emitting diode, an organic light emitting diode, or oth er self-emissive elements. For example, each pixel structure PS includes three light emitting elements LD1, LD2, and LD3, and the three light emitting elements LD1, LD2, and LD3 may respectively have different light colors. For example, the light emitting element LD1 may emit red light, the light emitting element LD2 may emit green light, and the light emitting element LD3 may emit blue light, so that each island portion 120 may form one pixel of the display device 10, thereby implementing full-color display. However, there is no particular limitation on the number or the light color of the light emitting element LD. In some embodiments, each island portion 120 may include one, two, four, or more light emitting elements LD.

For example, the pixel structure PS may further include transistors T11, T12, and T13, transistors T21, T22, and T23, transistors T31, T32, and T33, and capacitors C1, C2, and C3 respectively disposed corresponding to the light emitting elements LD1, LD2, and LD3. The gates of the transistors T11, T12, and T13 may be electrically connected to the corresponding bridge portion 130 via a signal line SL (such as serving as a scan line) to receive gate signals via the corresponding bridge portion 130. The sources of the transistors T11, T12, and T13 may be respectively electrically connected to the corresponding bridge portion 130 via signal lines DL1, DL2, and DL3 (such as serving as data lines) to receive source signals via the corresponding bridge portion 130. The drains of the transistors T11, T12, and T13 may be respectively electrically connected to the gates of the transistors T21, T22, and T23 to control the on or off of the transistors T21, T22, and T23. The sources of the transistors T21, T22, and T23 and the cathodes of the light emitting elements LD1, LD2, and LD3 may be respectively electrically connected to corresponding bridge portion 130 via signal lines Vdd and Vss (such as serving as power lines) to be respectively electrically connected to a voltage source via the corresponding bridge portion 130. The drains of the transistors T21, T22, and T23 may be respectively electrically connected to the sources of the transistors T31, T32, and T33, the gates of the transistors T31, T32, and T33 may be respectively electrically connected to a signal line EM, the drains of the transistors T31, T32, and T33 may be respectively electrically connected to the anodes of the light emitting elements LD1, LD2, and LD3, and the transistors T31, T32, and T33 may serve as switching elements, so as to respectively control the light emitting time of the light emitting elements LD1, LD2, and LD3. In addition, the two terminals of the capacitors C1, C2, and C3 may be respectively electrically connected to the drains of the transistors T11, T12, and T13 and the sources of the transistors T21, T22, and T23, and the transistors T11, T12, and T13 may respectively control the charging time of the capacitors C1, C2, and C3. The transistors T11, T12, and T13 and the transistors T21, T22, and T23 may respectively provide stable currents to the light emitting elements LD1, LD2, and LD3 within one frame time. In addition, the capacitors C1, C2, and C3 may maintain the gate voltages of the transistors T21, T22, and T23 after the scan pulse signals of the transistors T11, T12, and T13 end, thereby providing continuous driving currents for the light emitting elements LD1, LD2, and LD3 until the end of one frame time.

In some embodiments, the bridge portion 130 includes signal lines 140 and 141. The signal lines 140 and 141 may be located in the bridge region AB and extend to the connection region IE and are electrically connected to the pixel structure PS.

Please refer to FIG. 1C. The display device 10 further includes the inorganic insulating pattern 150. The inorganic insulating pattern 150 may be disposed in the connection region IE. In other words, the inorganic insulating pattern 150 may be disposed at a connection point between the island portion 120 and the bridge portion 130.

Please refer to FIG. 1C and FIG. 1D together. In some embodiments, the inorganic insulating pattern 150 may be disposed near an uphill section of the signal line 141 (i.e., a bent section of the signal line 141 due to terrain undulation). When the display device 10 is stretched or squeezed by an external force and is deformed, the uphill section in the connection region IE may be a place in the island portion 120 that is subjected to relatively large strain, and the configuration of the inorganic insulating pattern 150 may disperse the strain, thereby improving the strain bearing capacity of the display device 10.

The inorganic insulating pattern 150 may have a notch 151 (or a recess) to have an irregular outline. In some embodiments, the inorganic insulating pattern 150 has a rectangular outline having the notch 151 (or the recess). The orthographic projections of the signal lines 140 and 141 on the substrate 110 overlap with the orthographic projection of the notch 151 on the substrate 110. For example, the inorganic insulating pattern 150 may have two arc-shaped notches 151, and the signal lines 140 and 141 respectively overlap with the two arc-shaped notches 151. The notches 151 help to speed up an etching rate of a conductive material (for example, metal) during the etching process of forming the signal lines 140 and 141, thereby preventing the conductive material from remaining between the signal lines 140 and 141 and causing a short circuit between the signal lines 140 and 141.

In some embodiments, a part of the inorganic insulating pattern 150 overlapping with the signal lines 140 and 141 has a maximum size L1, a part of the inorganic insulating pattern 150 not overlapping with the signal lines 140 and 141 has a maximum size L2, and the maximum size L1 is smaller than the maximum size L2.

In some embodiments, the display device 10 further includes signal lines 143, 145, and 147. The signal lines 143, 145, and 147 may substantially overlap with the signal line 141. The signal lines 141, 143, 145, and 147 may respectively transmit different signals, such as scan signals, data signals, and power signals, but not limited thereto. In some embodiments, any two of the signal lines 141, 143, 145, and 147 may transmit the same signal.

In some embodiments, the inorganic insulating pattern 150 is disposed between the signal line 141 and the substrate 110. In some embodiments, the inorganic insulating pattern 150 is disposed between the additional signal line 143 and the signal line 145, so that the additional signal line 143 is located between the substrate 110 and the inorganic insulating pattern 150. In some embodiments, the inorganic insulating pattern 150 may be disposed between the signal line 141 and the substrate 110, and another inorganic insulating pattern 150 is disposed between the additional signal line 143 and the signal line 145, so that the additional signal line 143 is located between the substrate 110 and another inorganic insulating pattern 150. In some other embodiments, the inorganic insulating pattern 150 is disposed between the additional signal line 143 and the signal line 145, so that the additional signal line 143 is located between the substrate 110 and the inorganic insulating pattern 150, and the inorganic insulating pattern 150 is not disposed between the signal line 141 and the substrate 110.

In some embodiments, the display device 10 further includes an organic insulating layer 160. The organic insulating layer 160 may surround the inorganic insulating pattern 150. The organic insulating layer 160 may also be located between any two of the signal lines 141, 143, 145, and 147. In some embodiments, the organic insulating layer 160 may surround each of the signal lines 141, 143, 145, and 147. The material of the organic insulating layer 160 may include, for example, acrylic, siloxane, polyimide, epoxy, etc., but not limited thereto. In some embodiments, the organic insulating layer 160 may have a single-layer structure or a multi-layer structure. When the organic insulating layer 160 has the multi-layer structure, respective layers in the multi-layer structure may include the same material as each other or materials different from each other.

Please refer to FIG. 1E and FIG. 1G. The display device 10 may further include multiple inorganic insulating patterns 152 disposed in the bridge region AB. A part of the inorganic insulating patterns 152 may overlap with the signal lines 140 and 141, and the inorganic insulating patterns 152 may be physically separated from each other by the organic insulating layer 160. In other words, the inorganic insulating patterns 152 may be discontinuously distributed between the signal lines 140 and 141 and the substrate 110, and the organic insulating layer 160 may surround each inorganic insulating pattern 152. For example, the dotted lines in FIG. 1E may represent the multi-layer structure of the organic insulating layer 160.

In some embodiments, the display device 10 further includes signal lines 142, 144, and 146. The signal lines 142, 144, and 146 may substantially overlap with the signal line 140. In some embodiments, a part of the inorganic insulating patterns 152 is located between any two of the signal lines 140, 142, 144, and 146 and/or between any two of the signal lines 141, 143, 145, and 147, so as to improve the adhesion between the organic insulating layer 160 and the signal lines 140 to 147. In some embodiments, any one of the signal lines SL, DL1, DL2, DL3, Vdd, Vss, and EM as shown in FIG. 1B may be respectively electrically connected to any one of the signal lines 140 to 147.

In some embodiments, the signal lines 140 to 147 have rectangular-strip appearances, but not limited thereto. The signal lines 140 to 147 may have good electrical conductivity and ductility or stretchability. Specifically, the materials of the signal lines 140 to 147 may have relatively small resistivity. For example, the resistivity of the signal lines 140 to 147 may be between 1.5×10⁻⁵ and 5×10⁻⁴ Ω*mm. For example, the signal lines 140 to 147 may include metal materials such as titanium, aluminum, copper, and silver or alloys thereof, but not limited thereto. In some embodiments, the signal lines 140 to 147 further include conductive oxide (for example, indium tin oxide, zinc aluminum oxide, zinc gallium oxide, zinc indium oxide, etc.), conductive polymer (for example, poly(3,4-ethylenedioxythiophene): poly(styrene sulfonate) (PEDOT:PSS)), metal nanowires (for example, silver nanowires), or combinations thereof. In some embodiments, the signal lines 140 to 147 may respectively have a single-layer structure or a multi-layer structure. When the signal lines 140 to 147 have the multi-layer structure, respective layers in the multi-layer structure may include the same material as each other or materials different from each other.

Please refer to FIG. 1F. In some embodiments, a part of the inorganic insulating pattern 152 does not overlap with the signal lines 140 to 147. For example, a part of the inorganic insulating patterns 152 does not overlap with the signal lines 140 and 141 and is located between the organic insulating layer 160 and the substrate 110, so as to improve the adhesion between the organic insulating layer 160 and the substrate 110. In some embodiments, the inorganic insulating patterns 152 are located between multiple layers of the multi-layer structure of the organic insulating layer 160, so that the organic insulating layer 160 surrounds each inorganic insulating pattern 152. In this way, by the support or the buffering of each inorganic insulating pattern 150, 152, when the display device 10 is deformed, the stress borne by the connection region IE of the island portion 120 may be reduced, while dispersing the amount of strain of the bridge portion 130 in the stretched state, so that the amount of stretching that the connection region IE and the bridge portion 130 may withstand is increased, thereby improving the stretchability and the elastic recovery of the display device 10.

In some embodiments, a part of the inorganic insulating patterns 152 belongs to the same film layer, and a part of the inorganic insulating patterns 152 belongs to different film layers. The materials of the inorganic insulating patterns 150 and 152 may include, for example, silicon nitride (SiNx), silicon oxide (SiOx), silicon oxynitride (SiNxOy), titanium oxide (TiO), etc., but not limited thereto. In some embodiments, the inorganic insulating pattern 150, 152 may have a single-layer structure or a multi-layer structure. When the inorganic insulating pattern 150, 152 has the multi-layer structure, respective layers in the multi-layer structure may include the same material as each other or materials different from each other.

Please refer to FIG. 1G. In some embodiments, the display device 10 further includes an inorganic insulating pattern 154. The inorganic insulating pattern 154 is located in the island region AI. The inorganic insulating pattern 154 may, for example, serve as an insulating layer between a transistor and a conductive film layer of a capacitor. For example, a part of the transistors T11, T12, T13, T21, T22, T23, T31, T32, and T33 and the capacitors C1, C2, and C3 in the pixel structure PS shown in FIG. 1B may be located below the inorganic insulating pattern 154 (i.e., between the inorganic insulating pattern 154 and the substrate 110), and another part of the transistors T11, T12, T13, T21, T22, T23, T31, T32, and T33 and the capacitors C1, C2, and C3 may be located above the inorganic insulating pattern 154. In some embodiments, any one of the signal lines 140 to 147 may be electrically connected to a component below the inorganic insulating pattern 154 via a through hole (not shown) in the inorganic insulating pattern 154. For example, when the signal line 140 serves as the signal line SL for transmitting a scan signal and the gates of the transistors T11, T12, and T13 are located below the inorganic insulating pattern 154, the signal line 140 may be electrically connected to the gates of the transistors T11, T12, and T13 via the through hole in the inorganic insulating pattern 154. In some embodiments, the materials of the gates of the transistors T11, T12, and T13 may not be ductile or stretchable.

In some embodiments, there is a connection plane CP between the connection region IE and the bridge region AB. The inorganic insulating pattern 150 has a maximum size W in a direction parallel to the nearest connection plane CP, the connection region IE has a maximum size L in a direction parallel to the nearest connection plane CP, and L/6≤W≤L/2. In some embodiments, the maximum size W is about L/3.

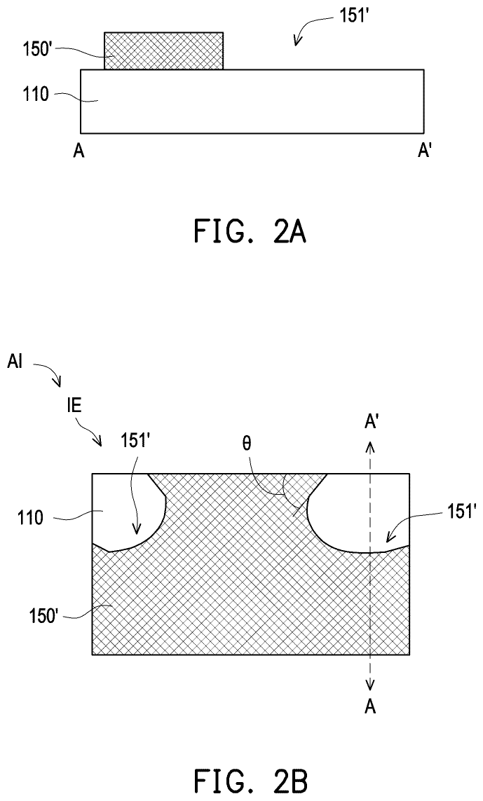

FIG. 2A to FIG. 4A are partial cross-sectional schematic views of steps of a method for manufacturing the display device 10 of FIG. 1A. FIG. 2B to FIG. 4B are respectively partial schematic top schematic views of FIG. 2A to FIG. 4A. FIG. 2A to FIG. 4A are respectively top schematic views along a line A-A′ of FIG. 2B to FIG. 4B.

Please refer to FIG. 2A and FIG. 2B together. An inorganic insulating pattern 150′ having a notch 151′ is formed in the predetermined connection region IE on the substrate 110. The inorganic insulating pattern 150′ may have an acute angle θ at a place adjacent to the notch 151′. The inorganic insulating pattern 150′ may be formed by adopting a thin film deposition process, a photolithography process, and an etching process. In some embodiments, the inorganic insulating pattern 152 is also simultaneously formed in the predetermined bridge region AB on the substrate 110, and the bridge region AB may be adjacent to the connection region IE. In other words, the inorganic insulating pattern 152 and the inorganic insulating pattern 150′ may belong to the same film layer.

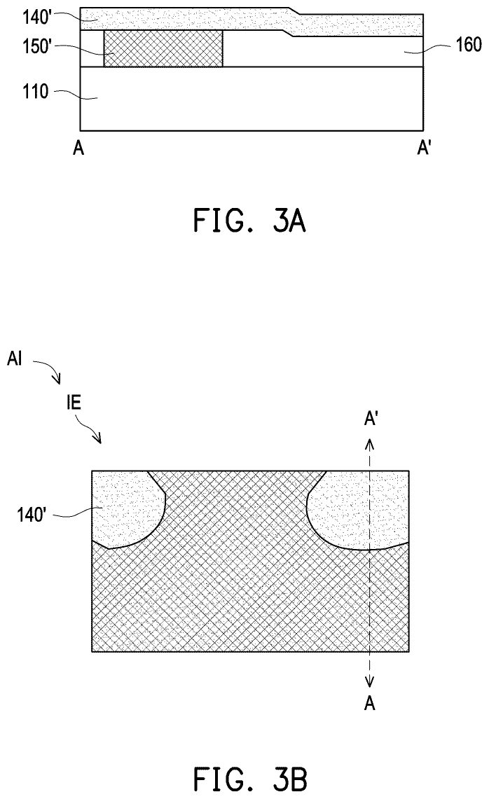

Please refer to FIG. 3A and FIG. 3B together. A coated conductive layer 140′ is formed on the substrate 110 and the inorganic insulating pattern 150′. The conductive layer 140′ may be formed by adopting a thin film deposition process (for example, a physical vapor deposition process or an electroplating process). Before forming the conductive layer 140′, the organic insulating layer 160 may be first formed on the substrate 110 and around the inorganic insulating pattern 150′. In some embodiments, the organic insulating layer 160 may be formed by adopting a spin coating process. The organic insulating layer 160 enables the conductive layer 140′ to be formed on a relatively flat surface.

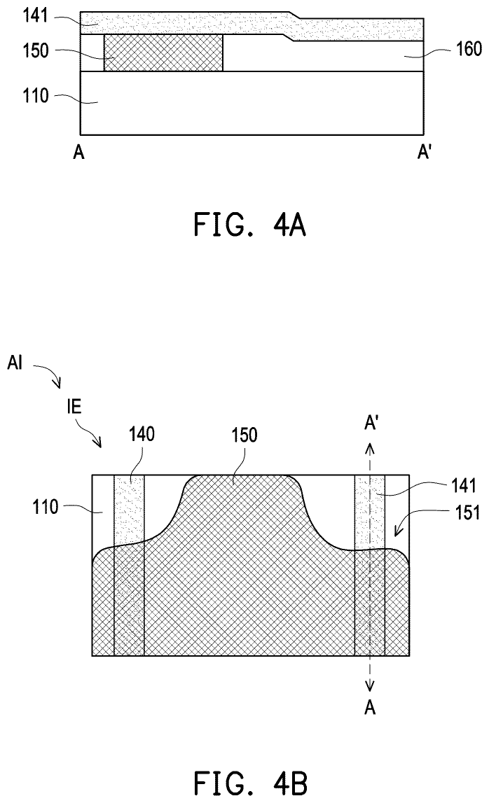

Please refer to FIG. 4A and FIG. 4B together. The conductive layer 140′ is etched to form the signal lines 140 and 141. The conductive layer 140′ may be etched using, for example, an isotropic etching process. The signal lines 140 and 141 may be located in the bridge region AB, and the signal lines 140 and 141 may extend from the bridge region AB to the connection region IE. In some embodiments, the signal lines 140 and 141 may also be electrically connected from the connection region IE to other regions in the island region AI, such as an element region where a transistor or a capacitor is disposed. By overlapping the predetermined formation positions of the signal lines 140 and 141 with the notch 151′ of the inorganic insulating pattern 150′, during the process of etching the conductive layer 140′, a place adjacent to the notch 151′ may have a faster etching rate, so as to prevent the material of the conductive layer 140′ from remaining between the signal lines 140 and 141, thereby reducing the possibility of a short circuit between the signal lines 140 and 141.

In addition, since an etchant used during the etching process not only removes the conductive layer 140′ but also removes the inorganic insulating pattern 150′, after the signal lines 140 and 141 are formed, the acute angle θ of the inorganic insulating pattern 150′ is removed, and the shape of the notch 151′ is slightly changed to form the inorganic insulating pattern 150 having the notch 151, wherein the shapes or the outlines of the notch 151 and the notch 151′ are slightly different. In some embodiments, the etchant used during the etching process includes chlorine (Cl₂), boron trichloride (BCl₃), or a combination thereof. In some embodiments, the etching selectivity of the etchant to the conductive layer 140′ and the inorganic insulating pattern 150′ is about 5˜8:1, such as about 6.25:1.

In some embodiments, after the signal lines 140 and 141 are formed, the organic insulating layer 160, the signal lines 142 to 147, and other inorganic insulating patterns 150 and 152 are formed, as shown in FIG. 1D to FIG. 1F. After the signal lines 140 to 147 are formed, a light emitting element electrically connected to at least one of the signal lines 140 to 147 may be formed in the island region AI.

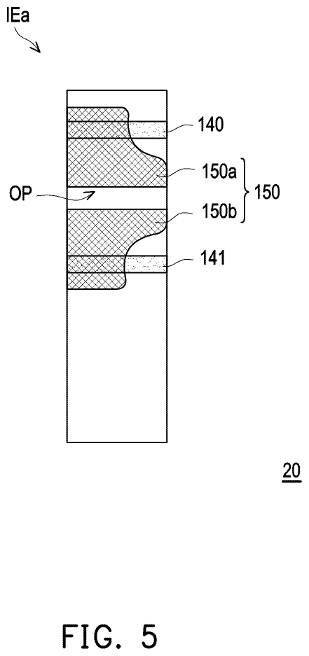

FIG. 5 is a top schematic view of a connection region IEa of a display device 20 according to an embodiment of the disclosure. In FIG. 5, the display device 20 may be considered as another implementation of the display device 10 of FIG. 1A to FIG. 1G, and the display device 20 may have all components of the display device 10. The present embodiment continues to use the same or similar reference numerals and some content as those of the embodiment of FIG. 1A to FIG. 1G.

Compared with the connection region IE of the display device 10 shown in FIG. 1C, the connection region IEa of the display device 20 shown in FIG. 5 is mainly different in that the inorganic insulating pattern 150 of the display device 20 may have an opening OP. The opening OP may divide the inorganic insulating pattern 150. For example, the opening OP separates the inorganic insulating pattern 150 into inorganic insulating patterns 150a and 150b. The inorganic insulating patterns 150a and 150b are physically separated from each other to promote the etching of the material of the conductive layer 140′ located between the predetermined positions of the signal line 140 and the signal line 141 during the etching process of the conductive layer 140′, and even further increase the local etching rate to prevent the material of the conductive layer 140′ from remaining between the signal line 140 and the signal line 141. In other words, the signal line 140 and the signal line 141 are adjacent signal lines patterned from the same conductive layer 140′. In some embodiments, the signal line 140 is electrically connected to, for example, a scan signal source, and the signal line 141 is electrically connected to, for example, a data signal source, but not limited thereto. By the configuration of the inorganic insulating pattern 150, the material of the conductive layer 140′ is prevented from remaining between the signal line 140 and the signal line 141, which can prevent the signal lines 140 and 141 connected to different signal sources from short circuiting and causing signal abnormality, thereby improving the yield of the display device 20.

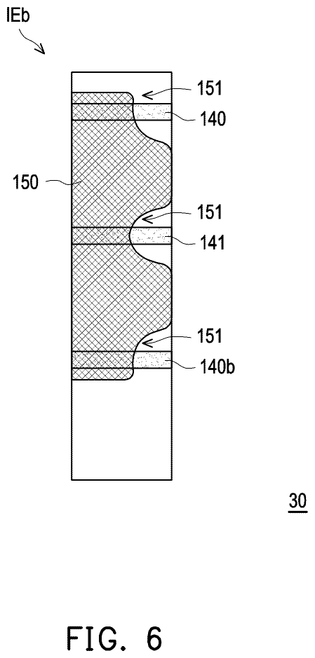

FIG. 6 is a top schematic view of a connection region IEb of a display device 30 according to an embodiment of the disclosure. In FIG. 6, the display device 30 may be considered as another implementation of the display device 10 of FIG. 1A to FIG. 1G, and the display device 30 may have all components of the display device 10. The present embodiment continues to use the same or similar reference numerals and some content as those of the embodiment of FIG. 1A to FIG. 1G.

Compared with the connection region IE of the display device 10 shown in FIG. 1C, the connection region IEb of the display device 30 shown in FIG. 6 is mainly different in that in addition to the signal lines 140 and 141, the display device 30 further includes a signal line 140b substantially parallel to the signal lines 140 and 141, the inorganic insulating pattern 150 of the display device 30 may have more notches 151, and the notches 151 respectively overlap with the signal lines 140, 141, and 140b to prevent the conductive layer 140′ from remaining between the signal lines 140, 141, and 140b, ensuring that a short circuit does not occur between the signal lines 140, 141, and 140b.

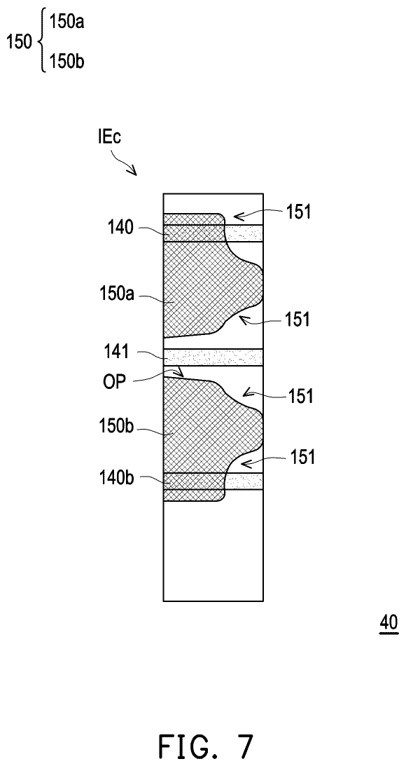

FIG. 7 is a top schematic view of a connection region IEc of a display device 40 according to an embodiment of the disclosure. In FIG. 7, the display device 40 may be considered as another implementation of the display device 10 of FIG. 1A to FIG. 1G, and the display device 40 may have all components of the display device 10. The present embodiment continues to use the same or similar reference numerals and some content as those of the embodiment of FIG. 1A to FIG. 1G.

Compared with the connection region IE of the display device 10 shown in FIG. 1C, the connection region IEc of the display device 40 shown in FIG. 7 is mainly different in that in addition to the signal lines 140 and 141, the display device 40 further includes a signal line 140b substantially parallel to the signal lines 140 and 141, the inorganic insulating pattern 150 of the display device 40 may have the opening OP and more notches 151, and the signal lines 140, 141, and 140b may respectively overlap with the notches 151. The opening OP may divide the inorganic insulating pattern 150 into the inorganic insulating patterns 150a and 150b physically separated from each other. The middle signal line 141 may completely overlap with the opening OP. The opening OP may be further communicated with the adjacent notch 151. The signal line 141 may not overlap with the inorganic insulating patterns 150a and 150b. In this way, it can be ensured that the conductive layer 140′ does not remain between the signal line 140 and the signal line 141 and between the signal line 141 and the signal line 140b.

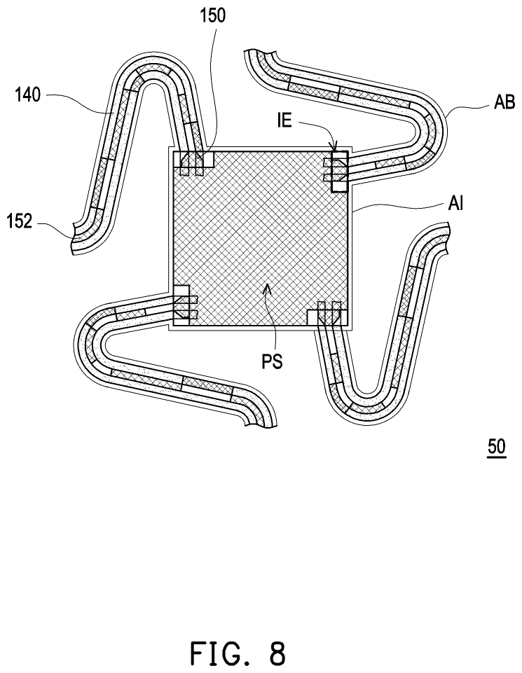

FIG. 8 is a partial top schematic view of a display device 50 according to an embodiment of the disclosure. In FIG. 8, the display device 50 may be considered as another implementation of the display device 10 of FIG. 1A to FIG. 1G, and the display device 50 may have all components of the display device 10. The present embodiment continues to use the same or similar reference numerals and some content as those of the embodiment of FIG. 1A to FIG. 1G. The display device 50 has the island region AI, the bridge region AB, and the connection region IE adjacent to the island region AI and connected to the bridge region AB. The display device 50 includes the pixel structure PS located in the island region AI, the inorganic insulating pattern 150 located in the connection region IE, and the signal line 140 and the inorganic insulating pattern 152 located in the bridge region AB. Compared with the U-shaped bridge region AB of the display device 10 shown in FIG. 1G, the display device 50 shown in FIG. 8 is mainly different in that the bridge region AB of the display device 50 may have a V-shaped outline.

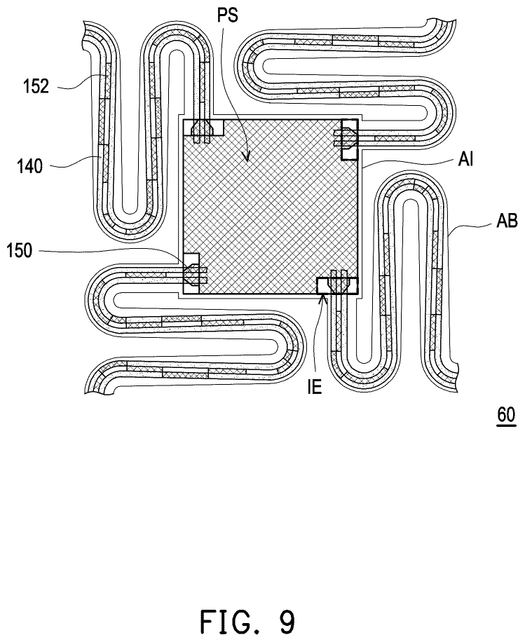

FIG. 9 is a partial top schematic view of a display device 60 according to an embodiment of the disclosure. In FIG. 9, the display device 60 may be considered as another implementation of the display device 10 of FIG. 1A to FIG. 1G, and the display device 60 may have all components of the display device 10. The present embodiment continues to use the same or similar reference numerals and some content as those of the embodiment of FIG. 1A to FIG. 1G. The display device 60 has the island region AI, the bridge region AB, and the connection region IE adjacent to the island region AI and connected to the bridge region AB. The display device 60 includes the pixel structure PS located in the island region AI, the inorganic insulating pattern 150 located in the connection region IE, and the signal line 140 and the inorganic insulating pattern 152 located in the bridge region AB. Compared with the U-shaped bridge region AB of the display device 10 shown in FIG. 1G, the display device 60 shown in FIG. 9 is mainly different in that the bridge region AB of the display device 60 may have an S-shaped outline.

In summary, the display device of the disclosure can improve the adhesion between the signal line and the organic insulating layer and between the substrate and the organic insulating layer by the inorganic insulating pattern disposed in the connection region, thereby improving the stretchability of the display device. In addition, by providing the inorganic insulating pattern with the notch, it can be ensured that the conductive material does not remain between the signal lines, thereby improving the yield and the reliability of the display device.

Although the disclosure has been disclosed in the above embodiments, the embodiments are not intended to limit the disclosure. Persons skilled in the art may make some changes and modifications without departing from the spirit and scope of the disclosure. Therefore, the protection scope of the disclosure shall be defined by the appended claims.

What is claimed is:

1. A display device, comprising:
a substrate, having an island region, a bridge region, and a connection region, wherein the connection region is adjacent to the island region and connected to the bridge region;
a pixel structure, disposed in the island region and comprising a light emitting element;
a signal line, located in the bridge region, extending to the connection region, and electrically connected to the pixel structure; and
a first inorganic insulating pattern, located in the connection region and having a notch,
wherein an orthographic projection of the signal line on the substrate overlaps an orthographic projection of the notch on the substrate.

2. The display device according to claim 1, wherein the notch has an arc-shaped outline.

3. The display device according to claim 1, wherein a part of the first inorganic insulating pattern overlapping with the signal line has a first maximum size, a part of the first inorganic insulating pattern not overlapping with the signal line has a second maximum size, and the first maximum size is smaller than the second maximum size.

4. The display device according to claim 1, wherein the first inorganic insulating pattern is located between the substrate and the signal line.

5. The display device according to claim 4, further comprising an additional signal line, wherein the additional signal line is located between the substrate and the first inorganic insulating pattern.

6. The display device according to claim 1, wherein the first inorganic insulating pattern has an opening, wherein the opening divides the first inorganic insulating pattern.

7. The display device according to claim 6, wherein the opening is communicated with the notch.

8. The display device according to claim 6, wherein the signal line overlaps with the opening.

9. The display device according to claim 1, wherein the signal line comprises a first signal line and a second signal line, and the first inorganic insulating pattern has a plurality of notches, wherein the first signal line and the second signal line respectively overlap with the notches.

10. The display device according to claim 9, wherein the first signal line and the second signal line are respectively connected to a first signal source and a second signal source.

11. The display device according to claim 1, further comprising a plurality of second inorganic insulating patterns, wherein the second inorganic insulating patterns are located in the bridge region and are physically separated from each other.

12. The display device according to claim 11, wherein a part of the second inorganic insulating patterns overlaps with the signal line, and another part of the second inorganic insulating patterns does not overlap with the signal line.

13. The display device according to claim 11, further comprising an organic insulating layer, wherein the organic insulating layer surrounds the signal line, the first inorganic insulating pattern, and the second inorganic insulating patterns.

14. The display device according to claim 1, wherein the light emitting element comprises a micro light emitting diode or an organic light emitting diode.

15. The display device according to claim 1, wherein the island region has a rectangular outline, and the bridge region has a U-shaped, V-shaped, or S-shaped outline.
